(19) United States
(12) Patent Application Publication
(10) Pub. No.: US 2005/0063158 A1
(43) Pub. Date: Mar. 24, 2005

(54) Cooling device for electronic and electrical components

(75) Inventors: Walter Thiele, Bonn (DE); Wulf Pries, Dortmund (DE); Michael Jeuschede, Herdecke (DE); Peter Hoffmann, Schwerte (DE)

Correspondence Address: LERNER AND GREENBERG, PA, P O BOX 2480, HOLLYWOOD, FL, 33022-2480, US

(73) Assignee: SGL Carbon AG

(21) Appl. No.: 10/942,372

(22) Filed: Sep. 16, 2004

(30) Foreign Application Priority Data
Sep. 16, 2003 (DE) 203 14 532.1

(51) Int. Cl. H05K 7/20

(52) U.S. Cl. 361/700; 361/704; 361/714; 361/720

(57) ABSTRACT

Cooling apparatus for electronic and electrical components, comprising a closed circuit, through which a cooling medium flows and which has an evaporator, an evaporator hood made from graphite material, fluid connections and a condenser, which makes do without moving parts and offers effective protection for the electronic and electrical components against a broad spectrum of electromagnetic radiation.

The present invention relates to an apparatus for dissipating heat from the surface of electronic and electrical components, such as computer processors, laser diodes, very small motors or power electronic components.

Electronic appliances produce lost heat from some of the electrical energy supplied to them, and this heat has to be dissipated in order to prevent the electronic components from failing. In particular for computers, it is necessary to dissipate the heat lost from the central processing unit (CPU).

According to the current state of the art, a CPU in a commercially available personal computer generates from 50 to 120 watts of power loss which has to be dissipated as heat. However, a power loss of greater than 120 W is likely in future processor generations. To ensure that the CPU continues to function, depending on the type of processor it is necessary to restrict the temperature at the CPU to temperatures of at most around 60° C. by cooling. In a complex electronic appliance, such as a personal computer, there are further components as well as the CPU whose maximum working temperature is likewise subject to restrictions. These include graphics cards and memory chip arrays as significant sources of heat losses.

Many manufacturers of the electronic components stipulate that the maximum interior temperature (local ambient temperature—LAT) in a housing, depending on the manufacturer, should be at most 50° C. Further stipulations for a cooling system for electronic appliances are that the weight of the cooling system should be limited and furthermore very high demands are imposed on the stability of the system on account of the need to transport the electronic appliances.

The noise of the cooling system is also an important criterion in assessing the system.

Apparatuses for cooling electronic components, in particular CPUs, by combinations of heat sinks and suitable fans, are generally known. In known arrangements of this type, either very large heat sinks and/or high-power fans are required. The latter lead to high noise levels and generate additional electromagnetic fields which interfere with the sensitive electronic components of the computer.

Moreover, as the size of the heat sinks used increases, so does their inherent weight, to produce a technical problem, since the securing structures surrounding the electronic component which is to be cooled cannot always withstand the required mechanical loads, and secondly, in particular in the case of laptops, the total weight of the computer plays a significant role for the user.

It is typical to use heat sinks made from metal, especially copper or aluminum, which are employed on account of their good properties in terms of the absorption and dissipation of heat. Heat sinks of this type are often equipped with fins or other structural features which increase the surface area. However, on account of the dead weight of the metals, the size of the heat sinks cannot be increased arbitrarily as desired, in particular for new generations of computer. For example, copper has a density of 8.96 g/cm³, and even aluminum still has a density of 2.70 g/cm³.

Furthermore, heatpipes are used to cool electronic appliances. These transport heat from the object which is to be cooled to a heat sink which is at a certain physical distance from the object. From there, the heat is dissipated, likewise with the aid of a fan.

For example, U.S. Pat. No. 6,288,895 discloses an apparatus for cooling electronic components in a computer which, in addition to a fan, makes use of a heatpipe for dissipating the lost heat flux from the heat-generating electronic component and the condenser of which is thermally connected to a heat exchanger in channel form which has heat exchange fins. One drawback of this apparatus is that on account of the horizontal arrangement the heatpipe requires a forced return for the refrigerant and consumes additional energy for the fan, which, furthermore, represents an undesired source of noise.

In recent times, heatpipe coolers without fans have also been disclosed. A drawback in both cases, however, is that the heat which is dissipated remains in the housing of the computer. Heatpipe coolers therefore generally require very good ventilation of the housing, which causes further noise.

Furthermore, heatpipe coolers are only permissible if the computer housings are shielded from radiofrequency (RF) radiation. If the heatpipes are directly connected to RF radiation sources, such as for example CPUs, they act as antennas and transmit this energy to the computer housing, which can then itself act as an antenna and radiate the energy at the resonant point. This strong electrosmog can in the long term be harmful to the health of computer users. Therefore, there are strict restrictions on the use of heatpipe coolers in particular in Europe.

The object of the present invention is to configure an apparatus as described above in such a manner that all the abovementioned drawbacks are overcome, and in particular the demands for a LAT in the housing of at most 50° C. are satisfied even for new generations of computer.

According to the invention, this object is achieved by providing a cooling apparatus which, without moving components such as fans and pumps, dissipates the waste heat from the object that is to be cooled and also operates very quietly and energy-efficiency and, moreover, offers effective protection against electromagnetic radiation.

According to the invention, the cooling apparatus comprises an evaporator unit which is connected to the object to be cooled and is also in turn connected to a physically remote steam condenser, from which a cooling medium is supplied to the evaporator unit purely under the force of gravity. The cooling medium changes from the liquid state to the vapor state, taking up heat as it does so, and is then fed back to the steam condenser, to which it releases the heat of evaporation which it has previously taken up again and is thereby liquefied, so as to form a closed circuit. The evaporator unit according to the invention comprises an evaporator, through which the cooling medium flows, and an evaporator hood made from graphite material, the main advantage of which is the strong electromagnetic shielding and absorption action of the graphite. Compared to the prior art, in which additional electromagnetic interference is produced by the fans, according to the invention not only is this interference eliminated, but even additional protection against other electromagnetic interference is installed.

The cooling apparatus is based on absorption cooling, which has long been known per se. However, it does not have any moving components, such as motors or pumps, and is therefore free from wear. Consequently, it operates virtually without noise. If corrosion-free and aging-resistant materials are used, the apparatus has a theoretically unlimited service life.

Furthermore, the apparatus is distinguished in particular by the fact that it does not require any additional mechanical, electrical or other energy, which causes additional costs, to operate. It functions purely using the waste heat produced by the object which is to be cooled itself. Furthermore, if a suitable cooling medium is selected, it already operates in relatively low working temperature ranges, for example even at room temperature. Also, there is no need for any complex electronic controls.

Furthermore, the apparatus according to the invention is equipped with an evaporator unit which is distinguished by a low weight. The evaporator, which preferably consists of a material with a high thermal conductivity, has a lightweight hood made from graphite or graphite-containing material. Graphite has a density in the range from 1.0 g/cm³ in the case of pressed flake graphite to 1.9 g/cm³ in the case of synthetic graphite and is therefore significantly more lightweight than metal.

In the case of synthetic graphite, the thermal conductivity can be over 100 W/mK, and in the case of flake graphite the thermal conductivity in the graphite layer plane can be more than 400 W/mK. As a result, an evaporator hood produced from graphite materials still offers additional local dissipation of heat.

According to a particular embodiment, the evaporator is produced from high-strength graphite-filled plastic compounds with a good thermal conductivity, thereby offering additional shielding against electromagnetic radiation.

According to a further embodiment, the evaporator hood may also be produced from graphite-filled plastic, or alternatively from impregnated graphite foil pieces marketed inter alia under the trade name ®SIGRAFLEX.

The present invention will now be explained in detail with reference to the appended drawings, in which

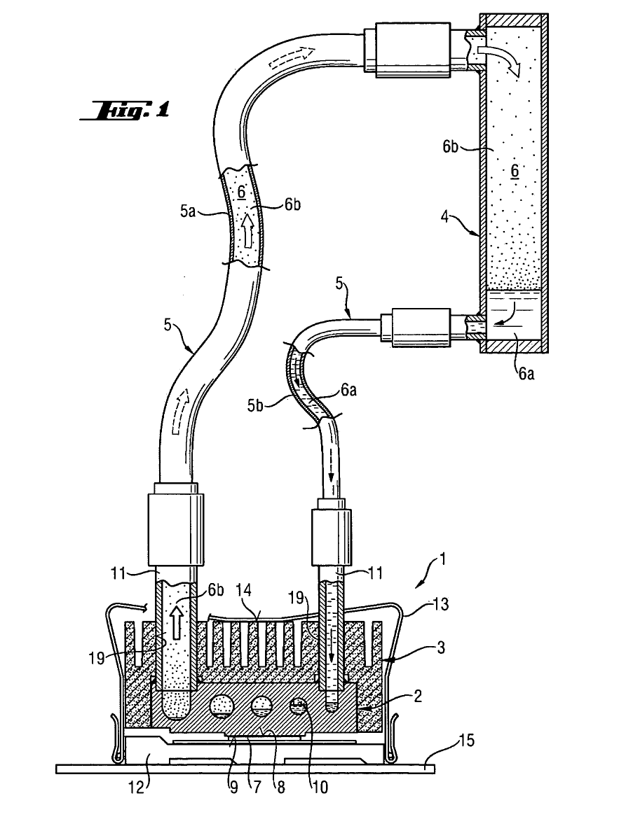

FIG. 1 diagrammatically depicts the apparatus according to the invention for dissipating heat from the surface of electronic and electrical components,

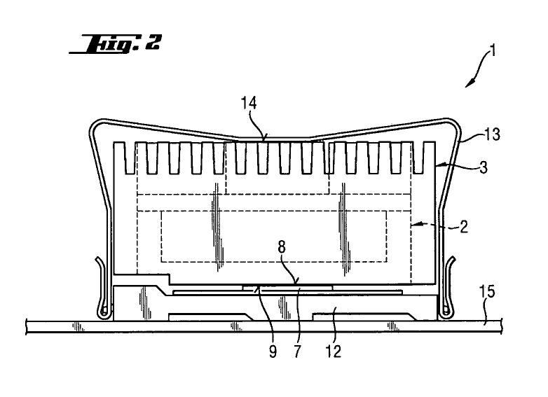

FIG. 2 shows a side view of an evaporator unit as installed in the computer,

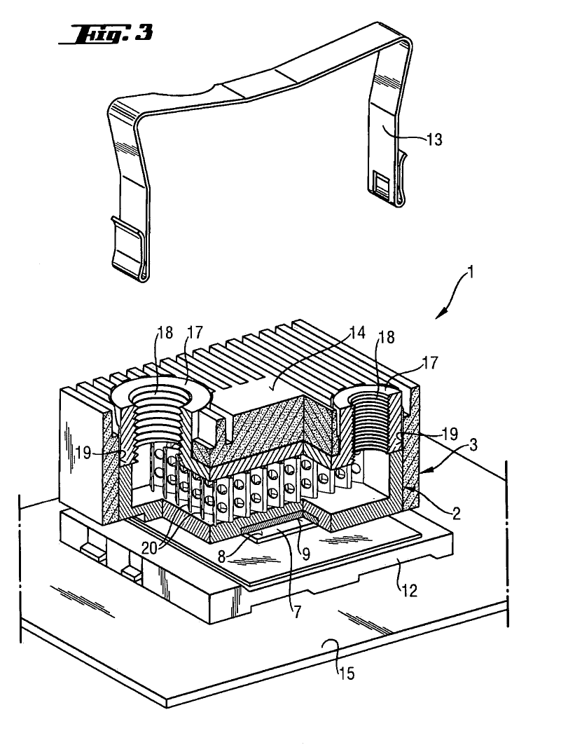

FIG. 3 shows a perspective cross-sectional view through an evaporator unit,

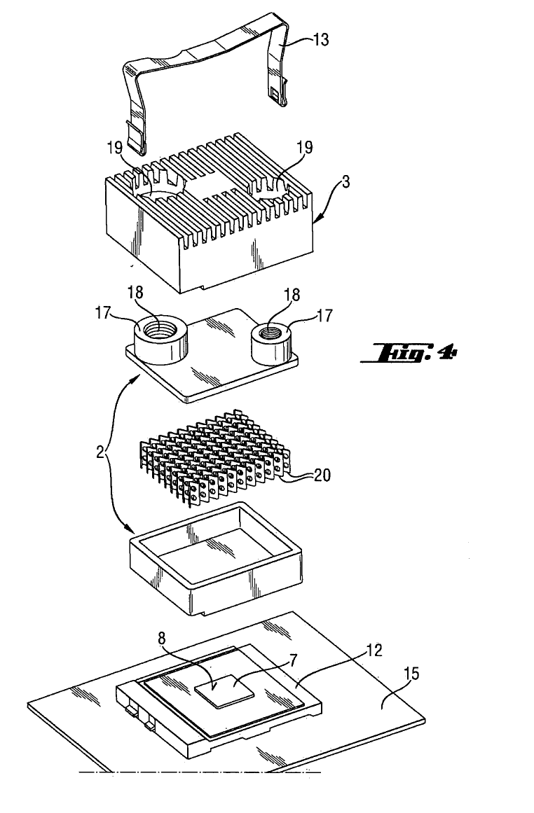

FIG. 4 shows a perspective, exploded view of an evaporator unit from above, and

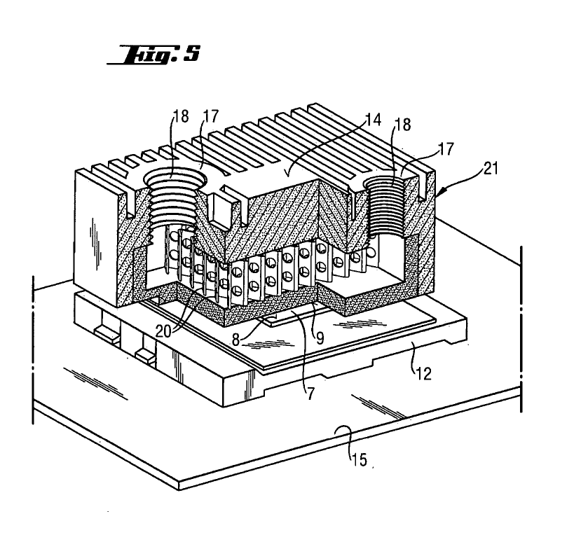

FIG. 5 shows a perspective sectional view through an evaporator unit which is substantially completely made from graphite material.

The apparatus according to the invention shown in FIG. 1 comprises the following main parts: evaporator unit (1), steam condenser (4), fluid connections (5) and a suitable cooling medium (6).

The evaporator unit (1) comprises an evaporator (2) made from a material with a high thermal conductivity and an evaporator hood (3) made from graphite or graphite-containing material. The metals copper or aluminum are used as preferred material for the evaporator (2). According to one particular embodiment of this invention, however, it is also possible for thermoplastic or preferably thermosetting plastic with a filling of at least 50% by weight of graphite powder or coke powder or mixtures thereof to be used as material for the evaporator (2). Complex evaporator geometries can be produced from a material of this type by means of industrial processing methods, such as for example injection molding.

The evaporator (2) is in thermal contact with the cooled electronic component (7) and absorbs heat from the latter. To ensure optimum heat transfer, the corresponding contact surface should be made as large as possible. In general, the cooled electronic component (7) has a planar adapter surface (8), onto which the adapter surface (9), which is as polished as possible, of the evaporator (2) fits. Thermally conductive pastes applied between them, which usually contain silver, not only improve the heat transfer from one material to the other but also, by virtue of their elastic properties, may also compensate for different thermal expansion properties.

In the interior, the evaporator (2) is configured in such a way that the liquid cooling medium (6a) can flow through it. It is ensured that the interface between evaporator (2) and cooling medium (6) flowing through it is made as large as possible. This is achieved, inter alia, by a meandering through-flow passage (10) or by elements which increase the surface area in the evaporator.

The evaporator (2) is connected to the steam condenser (4) via two fluid connections (5) in such a way that a closed circuit is formed. These fluid connections (5) comprise suitable commercially available coolant hoses or tubes which are pressure-tight to over 30 bar and have a maximum external diameter of 40 mm. They are both chemically and physically resistant to the cooling medium (6) and are pressure-tight and vacuum-tight.

In this context, it is important that what is referred to as the feed connection (5a), i.e. the fluid connection (5) which the cooling medium (6) flows through on the way from the evaporator (2) to the steam condenser (4), should have a larger cross section than the return connection (5b), in which the cooling medium (6) flows back from the steam condenser (4) to the evaporator (2).

As can be seen clearly from FIG. 1, the evaporator (2) is largely surrounded by an evaporator hood (3), with which it is in areal contact. This close contact is made possible by the use of suitable technical-grade adhesives. The evaporator hood (3) made from graphite material offers highly effective shielding and, at the same time, absorption of RF radiation. Therefore, the evaporator hood (3) made from graphite material overall offers protection over a broad electromagnetic frequency spectrum.

The graphite material of the evaporator hood (3) may consist of synthetic graphite, natural graphite, flake graphite or mixtures thereof, with additives, such as for example carbon black, carbon fibers, carbon nanotubes and/or metal and ceramic particles optionally also being added. In addition, the graphite material may be impregnated with metals in order to further improve the properties. The evaporator hood (3) may also be made from thermoplastic or thermosetting plastic with a filling of more than 50% by weight of graphite powder or coke powder or mixtures thereof, optionally together with the abovementioned additives.

The steam condenser (4) is preferably in the form of a closed hollow cylinder, but may also take other geometric forms. It consists of a material with a high thermal conductivity, such as for example copper, and is preferably protected from direct attack by a perforated metal sheet or other design measures.

The liquid cooling medium (6a) takes up heat in the evaporator (2) and thereby evaporates. The gaseous cooling medium (6b) passes into the condenser (4) through the feed. In the condenser (4), the gaseous cooling medium (6b) releases the heat of evaporation which it has previously taken up again and is thereby liquefied. The liquefied cooling medium (6a) flows back into the evaporator (2) via the return.

The cooling medium (6) consists of a chemical substance or a mixture of such substances with a boiling point of between −60° C. and 0° C. In particular propane and butane and the coolants R152a, R134a, R22 or their equivalents are used.

Evaporator (2) and steam condenser (4) have suitable connection stubs (11) for producing the fluid connections (5) required. The connection between connection stubs (11) and fluid connections (5) is secured by means of bayonet catches or similar design features to prevent it from coming loose.

In one preferred embodiment, the steam condenser (4) is of multi-stage structure. In this form, it comprises two or more hollow cylinders through which the cooling medium (6) flows in succession and which are as far as possible thermally decoupled from one another but are fluid-connected to one another. This is achieved by the use of hoses or tubes made from materials with as low a thermal conductivity as possible.

In a further preferred embodiment, the steam condenser (4) includes special internal fittings, such as metal heat dissipation plates, which are responsible for optimizing the circuit process.

A further embodiment is provided with pressure-tight and vacuum-tight shut-off valves. These are mechanically connected to the steam condenser (4), separating it from the fluid connections (5) and allowing hermetic closure of the steam condenser (4).

The steam condenser (4) is installed at a greater or lesser physical distance from the electronic component (7) which is to be cooled and/or the evaporator unit (1) depending on the particular application. The evaporator unit (1) and the steam condenser (4) may be installed horizontally, vertically or obliquely; some design features need to be modified depending on the desired spatial direction. In any event, the bottom edge of the steam condenser (4) must be located above the top edge of the evaporator (2). When used for computers, the steam condenser (4) is preferably secured outside the computer housing, with the fluid connections (5) then being led through suitable openings in the computer housing.

It is also possible for a plurality of evaporator units (1) to be simultaneously coupled to a condenser. This is the case, for example, in the case of computers, in which a plurality of components have to be cooled simultaneously.

FIG. 2 shows a side view of an evaporator unit (1) installed in the computer. The evaporator hood (3) made from graphite completely encloses the evaporator (2). The electronic component (7) to be cooled, in this case a CPU, is secured to a CPU base (12). As can be seen, the evaporator hood (3) is adapted to the specific design of the base (12) in this case. This base is in turn located on the circuit board (15). A commercially available pressure-exerting clip (13), which is hooked to the CPU base (12), presses the evaporator unit (1) onto the electronic component (7). To ensure that the mechanical loads on the fins of the evaporator hood (3) are not excessive, there is a pressure-exerting surface (14), against which the pressure-exerting clip (13) bears, on the top side of the evaporator hood (3). The mounting of the cooling apparatus according to the invention, specifically the evaporator unit (1), on the electronic components (7) that are to be cooled therefore does not require much adjustment on the part of the user, since in this case he can use commercially available pressure-exerting clips (13) which are generally already present in the computer.

FIG. 3 shows a section through an evaporator unit (1). This figure reveals the evaporator hood (3) surrounding the evaporator (2) and having the pressure-exerting surface (14). The evaporator (2) illustrated has a through-flow chamber (16) for the cooling medium (6) and threaded stubs (17) with an internal screw thread (18) for the connection stubs (11). The internal screw thread may also be dispensed with if the connection stubs (11) are directly joined to the evaporator (2), for example by a soldered joint. The same also applies to the connection stubs (11) at the steam condenser (4).

In the example shown in FIG. 3, the through-flow chamber (16) is provided with vertically arranged perforated metal sheets (20), which are responsible for improving the cooling of the electronic component (7) by increasing the heat-exchange surface area. This effect can also be achieved by the through-flow chamber (16) being equipped, for example, with metal wool, thermally conductive foams, powders or fibers, meshes, lamellar foils or metal sheets or meandering tube systems.

FIG. 4 shows a perspective view of an evaporator unit (1). This figure clearly reveals the pressure-exerting surface (14) and bores (19) with a diameter which is slightly larger than the external diameter of the threaded stubs (17).

FIG. 5 shows a perspective, sectional illustration of an evaporator unit (21) which is made completely from graphite-containing material. Cooling apparatuses according to the invention have successfully been tested for the cooling of computer components and of high-load circuits for wind generators and welding machines. The required LAT in the computer housings of at most 50° C. was achieved irrespective of the type and number of cooled computer components.

1-18. (canceled).

19. A cooling apparatus for electronic and electrical components, comprising:
a closed cooling circuit conducting a cooling medium substantially without moving mechanical components;
an evaporator unit, fluid connections, and a steam condenser connected in said cooling circuit.

20. The cooling apparatus according to claim 19, wherein said steam condenser is disposed physically separate from said evaporator unit, and said steam condenser having an outlet at a higher level than an inlet of said evaporator unit.

21. The cooling apparatus according to claim 19, wherein said cooling circuit has a feed connection carrying the cooling medium from said evaporator unit to said steam condenser and a return connection carrying the cooling medium from said steam condenser to said evaporator unit, said feed connection having an inner diameter from two to five times greater than a diameter of said return connection.

22. The cooling apparatus according to claim 19, wherein said evaporator unit has an evaporator and a surrounding evaporator hood, and said evaporator and said evaporator hood are areally glued to one another.

23. The cooling apparatus according to claim 22, wherein said evaporator is formed of a material having a thermal conductivity of at least 100 W/mK at 20° C., and said evaporator is formed with a through-flow chamber, through which the cooling medium flows, and two threaded stubs for connection stubs.

24. The cooling apparatus according to claim 22, wherein said evaporator consists of metal.

25. The cooling apparatus according to claim 22, wherein said evaporator consists of a material selected from the group consisting of copper and aluminum.

26. The cooling apparatus according to claim 22, wherein said evaporator is formed of thermoplastic or thermosetting plastic mixtures with a filler of more than 50% by weight of graphite powder or coke powder or mixtures thereof, and an optional additive in the filler or in the plastic material selected from the group consisting of carbon black, carbon fibers, carbon nanotubes, and metal and ceramic particles.

27. The cooling apparatus according to claim 23, wherein said through-flow chamber of said evaporator is equipped with elements for increasing a surface area thereof.

28. The cooling apparatus according to claim 27, wherein said elements for increasing the surface area are one of more elements selected from the group consisting of perforated metal sheets, metal wool, thermally conductive foams, powders or fibers, meshes, lamellar foils, metal sheets, and meandering tube systems.

29. The cooling apparatus according to claim 23, wherein said evaporator hood is formed of graphite material and with two bores having a diameter which is greater than an external diameter of said threaded stubs.

30. The cooling apparatus according to claim 29, wherein said evaporator hood is formed with ribs and a pressure-exerting surface for pressure-exerting clips.

31. The cooling apparatus according to claim 29, wherein said evaporator hood is formed of synthetic graphite, natural graphite, flake graphite, or mixtures thereof, and at least one optional additive selected from the group consisting of carbon black, carbon fibers, carbon nanotubes, and metal and ceramic particles added to the graphite or an optional impregnation with metals of the mixtures and the graphite or the mixtures.

32. The cooling apparatus according to claim 29, wherein said evaporator hood is formed of thermoplastic or thermosetting plastic mixtures with a filler of more than 50% by weight of graphite powder or coke powder or mixtures thereof, with an optional additive selected from the group consisting of carbon black, carbon fibers, carbon nanotubes and metal and ceramic particles added to the filler or the plastic or an optional impregnation with metals of the filler.

33. The cooling apparatus according to claim 19, wherein said steam condenser includes special internal fittings for optimizing a circuit process.

34. The cooling apparatus according to claim 33, wherein said special internal fittings are heat-conducting metal plates or meshes.

35. The cooling apparatus according to claim 19, wherein said steam condenser is a single-stage structure.

36. The cooling apparatus according to claim 19, wherein said steam condenser is a multi-stage structure.

37. The cooling apparatus according to claim 19, wherein said steam condenser is formed with one or more hollow cylinders through which the cooling medium flows in succession and which are thermally decoupled from one another but fluidically connected to one another.

38. The cooling apparatus according to claim 19, wherein said fluid connections are formed with coolant hoses or tubes that are pressure-tight to over 30 bar and that have a maximum outer diameter of 40 mm and that are chemically and physically resistant to the cooling medium and are pressure-tight and vacuum-tight and are secured to said evaporator and said steam condenser via connection stubs.

39. The cooling apparatus according to claim 38, wherein said coolant hoses or tubes are secured to said evaporator and said steam condenser by bayonet catches for preventing coming loose thereof.

40. The cooling apparatus according to claim 19, wherein said cooling medium consists of a chemical substance with a boiling point of between −60° C. and 0° C.

41. The cooling apparatus according to claim 19, wherein said cooling medium is selected from the group consisting of propane, butane, the coolants R152a, R134a, R22 or equivalents thereof, or mixtures thereof.

42. The cooling apparatus according to claim 19, wherein said evaporator unit is one of a plurality of evaporator units for cooling a plurality of electronic components, said plurality of evaporator units being fluidically connected to one or more said steam condensers.
